(19) United States
(12) Patent Application Publication
(10) Pub. No.: US 2017/0053954 A1
(43) Pub. Date: Feb. 23, 2017

(54) PREPARATION METHODS FOR THIN-FILM LAYER PATTERN, THIN-FILM TRANSISTOR AND ARRAY SUBSTRATE

(71) Applicant: BOE TECHNOLOGY GROUP CO., LTD., Beijing (CN)

(72) Inventors: Chien Hung LIU, Beijing (CN); Yu Cheng CHAN, Beijing (CN)

(21) Appl. No.: 15/308,229

(22) PCT Filed: Feb. 23, 2016
(86) PCT No.: PCT/CN2016/074360

§ 371 Date: Nov. 1, 2016

(30) Foreign Application Priority Data
Mar. 12, 2015 (CN) 201510108889.X

(51) Int. Cl. H01L 27/12

(52) U.S. Cl. CPC H01L 27/1288; H01L 27/1274

(57) ABSTRACT

Preparation methods for a thin-film layer pattern, thin-film transistor and array substrate. The preparation method for a thin-film layer pattern includes: providing a mask plate, the mask plate including a mask plate body and a hollowed portion arranged on same; placing the mask plate onto a substrate, and allowing a projection of the hollowed portion on the substrate to be overlapped with a projection of a thin-film layer pattern to be formed on the substrate; forming a thin film on the substrate on which the mask plate (10) is placed, wherein a first thin-film portion formed at the hollowed portion is disconnected from a second thin-film portion formed on the mask plate body; and stripping the mask plate, and reserving the first thin-film portion to form the thin-film layer pattern.

### TECHNICAL FIELD

Embodiments of the present disclosure relate to preparation methods of a thin film layer pattern, a thin film transistor and an array substrate.

### BACKGROUND

At present, by taking a thin film transistor as an example, a gate electrode, a semiconductor active layer, a source electrode and a drain electrode, for example, are all prepared by firstly defining a pattern of photoresist by a yellow light process and then etching away a thin film uncovered by the photoresist by an etching process so as to obtain a desired pattern, wherein the yellow light process includes coating, exposure and development of the photoresist.

However, along with improvement of a resolution of a product, when corresponding patterns are prepared by the yellow light process, the requirement for stability of manufacturing devices and particularly yellow light and etching devices is higher and higher, and if such two devices are instable or poor in status, it is easy to cause residues of the photoresist or poor etching, so that each layer of formed pattern has defects, wherein when the formed pattern is a conductive pattern, a short circuit or an open circuit and the like will occur.

In addition, preparation of all the corresponding patterns in related arts needs the yellow light process and the etching process, but the yellow light process includes coating, exposure and development of the photoresist, so that the preparation process is long in time and the risk and uncertainty in yield are easy to increase, and moreover, use of the conventional photoresist and liquid medicine related to etching is unbeneficial to reduction of production cost.

### SUMMARY

An embodiment of the invention provides a preparation method of a thin film layer pattern, comprising: providing a mask, the mask including a mask body and a hollow-out portion arranged on the mask body; placing the mask on a substrate, and enabling a projection of the hollow-out portion on the substrate to coincide with a projection of the thin film layer pattern to be formed on the substrate; forming a thin film on the substrate where the mask is placed, wherein a first portion of the thin film formed at the hollow-out portion is disconnected from a second portion of the thin film formed on the mask body; and stripping off the mask and reserving the first portion of the thin film on the substrate so as to form the thin film layer pattern.

In an example, the thin film is formed on the substrate provided with the mask by a sputtering method.

In an example, the mask is a metal mask.

In an example, a thickness of the metal mask is between 720 μm and 880 μm.

In an example, the thin film is an amorphous silicon thin film, and the method further comprises: after stripping off the mask, carrying out an annealing processing on the first portion of the thin film reserved on the substrate so as to crystallize the first portion of the thin film.

Another embodiment of the invention provides a preparation method of a thin film transistor, comprising: forming a gate electrode, a gate insulating layer, a semiconductor active layer, a source electrode and a drain electrode on a substrate, wherein at least one of the gate electrode, the semiconductor active layer, the source electrode and the drain electrode are prepared by any preparation method of the thin film layer pattern mentioned above.

In an example, a material of the semiconductor active layer includes a metal oxide semiconductor or poly silicon.

Another embodiment of the invention provides a preparation method of an array substrate, comprising: forming a thin film transistor and a pixel electrode electrically connected with a drain electrode of the thin film transistor on a substrate, the thin film transistor including a gate electrode, a gate insulating layer, a semiconductor active layer, a source electrode and the drain electrode; wherein, at least one of the gate electrode, the semiconductor active layer, the source electrode, the drain electrode and the pixel electrode are prepared by any preparation method of the thin film layer pattern mentioned above.

In an example, the method further comprises: forming a plurality of signal lines on the substrate, wherein the at least one signal line is prepared by any preparation method of the thin film layer pattern mentioned above.

Another embodiment of the invention provides a preparation method of an array substrate, comprising: forming a thin film transistor, a pixel electrode electrically connected with a drain electrode of the thin film transistor, and a common electrode on a substrate; the thin film transistor including a gate electrode, a gate insulating layer, a semiconductor active layer, a source electrode and the drain electrode; wherein, at least one of the gate electrode, the semiconductor active layer, the source electrode, the drain electrode, the pixel electrode and the common electrode are prepared by any preparation method of the thin film layer pattern mentioned above.

In an example, the method further comprises: forming a plurality of signal lines on the substrate, wherein the at least one signal line is prepared by any preparation method of the thin film layer pattern mentioned above.

Still another embodiment of the invention provides a preparation method of an array substrate, comprising: forming a thin film transistor and an electrode layer electrically connected with a drain electrode of the thin film transistor on a substrate; the thin film transistor including a gate electrode, a gate insulating layer, a semiconductor active layer, a source electrode and the drain electrode; wherein, at least one of the gate electrode, the semiconductor active layer, the source electrode, the drain electrode and the electrode layer electrically connected with the drain electrode are prepared by any preparation method of the thin film layer pattern mentioned above.

In an example, the method further comprises: forming a plurality of signal lines on the substrate, wherein the at least one signal line is prepared by any preparation method of the thin film layer pattern mentioned above.

In an example, the electrode layer is an anode or a cathode of a light-emitting diode.

### BRIEF DESCRIPTION OF THE DRAWINGS

In order to clearly illustrate the technical solution of the embodiments of the disclosure, the drawings of the embodiments or description in the prior art will be briefly described in the following. It is obvious that the described drawings are only related to some embodiments of the disclosure, and those skilled in the art also can obtain other drawings, without any inventive work, according to the drawings.

FIG. 1 is a flow schematic diagram of a preparation method of a thin film layer pattern provided by an embodiment of the present disclosure;

FIGS. 2a to 2d are schematic diagrams of related stages of a forming method of a thin film layer pattern provided by an embodiment of the present disclosure;

FIGS. 3a to 3i are schematic diagrams of related stages of a forming method of a thin film transistor provided by an embodiment of the present disclosure;

FIGS. 4a to 4b are schematic diagrams of related stages of a forming method of an array substrate provided by an embodiment of the present disclosure;

FIGS. 5a to 5b are schematic diagrams of related stages of another forming method of an array substrate provided by an embodiment of the present disclosure.

### DETAILED DESCRIPTION

The technical solution of the embodiments will be described in a clearly and fully understandable way in connection with the drawings related to the embodiments of the disclosure. It is obvious that the described embodiments are just a part but not all of the embodiments of the disclosure. Based on the embodiments of the disclosure, those skilled in the art can obtain other embodiment(s), without any inventive work, which should be within the scope of protection of the disclosure.

Unless otherwise defined, the technical terms or scientific terms here should be of general meaning as understood by those ordinarily skilled in the art. In the specification and claims of the patent application of the present disclosure, words such as “first”, “second” and the like do not denote any order, quantity, or importance, but rather are used for distinguishing different components. Similarly, words such as “a/an” or the like do not denote quantitative limitation, but rather indicate there is at least one. Words such as “include” or “comprise” and the like denote that elements or objects appearing before the words of “include” or “comprise” cover the elements or the objects enumerated after the words of “include” or “comprise” or equivalents thereof, not exclusive of other elements or objects. Words such as “connected” or “connecting” and the like are not limited to physical or mechanical connections, but may include electrical connection, either direct or indirect. Words such as “up”, “down”, “left”, “right” and the like are only used for expressing relative positional relationship, when the absolute position is a described object is changed, the relative positional relationship may also be correspondingly changed.

Embodiments of the present disclosure provide preparation methods of a thin film layer pattern, a thin film transistor and an array substrate, which can effectively promote product yield, and can shorten a production period and save cost.

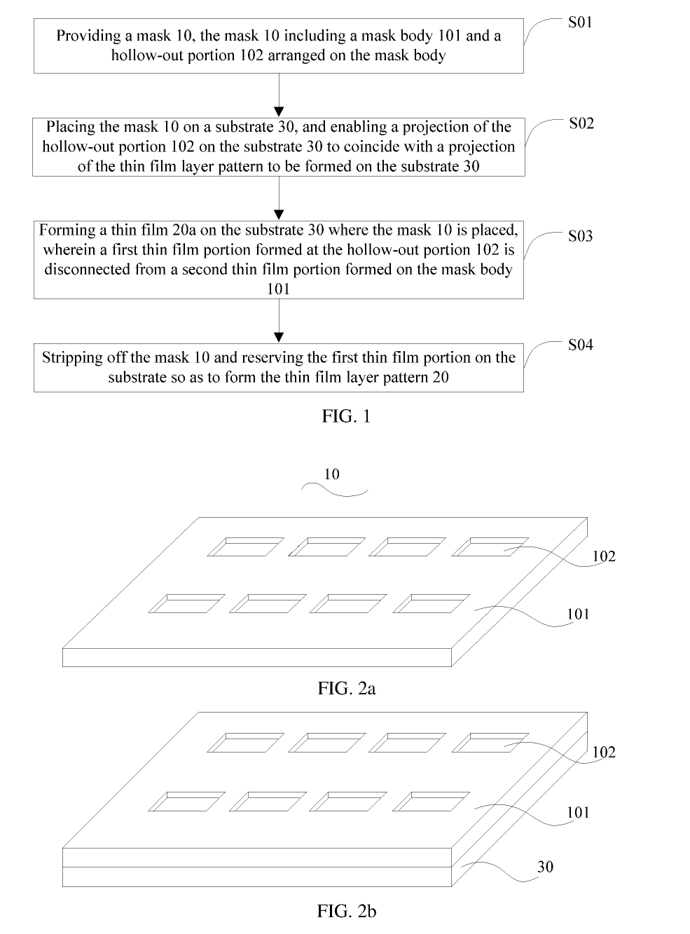

An embodiment of the present disclosure provides a preparation method of a thin film layer pattern. As illustrated in FIG. 1, the preparation method includes steps of:

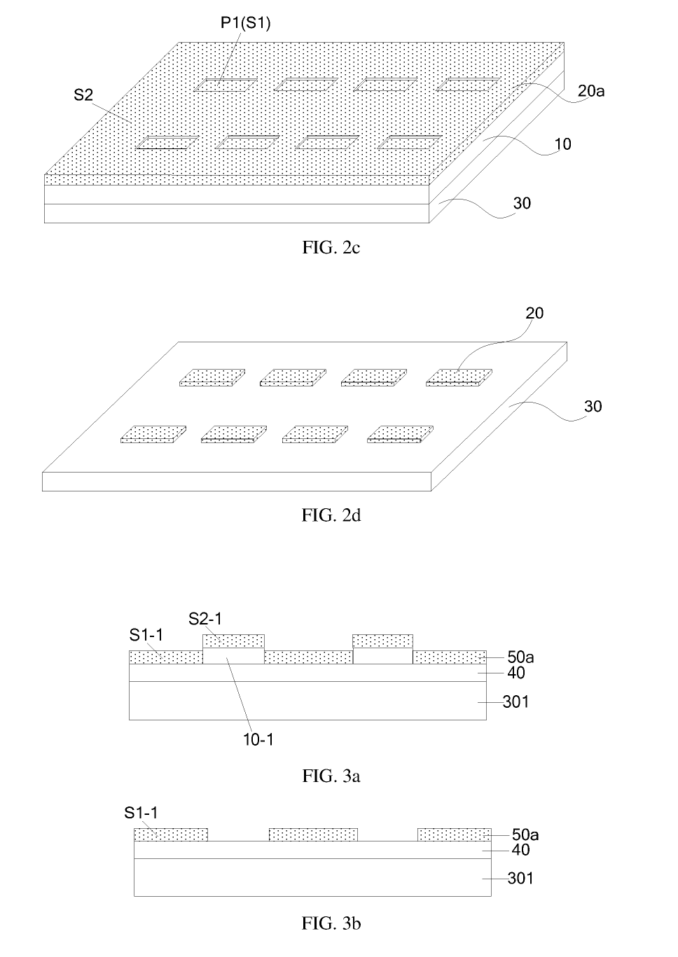

S01: as illustrated in FIG. 2a, providing a mask 10, the mask 10 including a mask body 101 and a hollow-out portion 102 arranged on the mask body.

Herein, a material of the mask 10 is not limited, and for example, the material of the mask 10 can be a material difficult to deform.

S02: as illustrated in FIG. 2b, placing the mask 10 on a substrate 30, and enabling a projection of the hollow-out portion 102 on the substrate 30 to coincide with a projection of the thin film layer pattern to be formed on the substrate 30.

For example, the substrate 30 can be a base substrate on which no pattern is formed, and also can be a substrate on which each layer of pattern is formed.

When the substrate is the substrate on which each layer of pattern is formed, the projection of the hollow-out portions 102 coincides with the projection of the thin film layer pattern to be formed on the substrate 30, i.e., the projection of the hollow-out portion 102 on the base substrate coincides with the projection of the thin film layer pattern to be formed on the base substrate.

Herein, the thin film layer pattern can be a conductive layer pattern, e.g., a gate electrode, a source electrode, a drain electrode and the like, also can be a semiconductor layer pattern, e.g., a semiconductor active layer, and certainly, also can be any other pattern, e.g., an insulating layer.

S03: as illustrated in FIG. 2c, forming a thin film 20a on the substrate 30 where the mask 10 is placed, wherein a first thin film portion S1 formed at the hollow-out portion 102 is disconnected from a second thin film portion S2 formed on the mask body 101.

A material of the thin film 20a can be a metal material, can also be a semiconductor material, which, for example, can be determined according to the thin film layer pattern expected to be formed.

Herein, the thin film portion S1 formed at the hollow-out portion 102 can be disconnected from the thin film portion S2 formed on the mask body 101 by controlling a thickness of the mask 10 and/or a process for forming the thin film 20a.

For example, the first thin film portion S1 formed at the hollow-out portion 102 can include a plurality of first sub thin film portions P1, and each first sub thin film portions P1 is disconnected from the second thin film portion S2 formed on the mask body 101.

S04: as illustrated in FIG. 2d, stripping off the mask 10 and reserving the first thin film portion S1 on the substrate so as to form the thin film layer pattern 20.

When the thin film 20a is formed on the substrate 30 where the mask 10 is placed, the thin film 20a is not only formed on the mask body 101, but also is formed in the hollow-out portion 102, and thus, when the mask 10 is stripped off, the second thin film portion S2 on the mask body 101 can be taken away together with the mask 10, so that the first thin film portion S1 at the hollow-out portion 102 is reserved on the substrate 30 to serve as the thin film layer pattern 20.

It should be noted that in the embodiment of the present disclosure, the thin film 20a refers to a layer of thin film prepared from a certain material on the substrate by deposition, sputtering or other processes, and the thin film layer pattern is a thin film portion of the formed thin film, which is finally reserved on the substrate 30. For example, when the thin film 20a is a metal thin film, the thin film layer pattern 20 can be a gate electrode, or a source electrode and a drain electrode; and when the thin film 20a is a semiconductor thin film, the thin film layer pattern 20 can be a semiconductor active layer.

The embodiment of the present disclosure provides the preparation method of the thin film layer pattern. The preparation method includes: providing the mask 10, the mask 10 including the mask body 101 and the hollow-out portion 102 arranged on the mask body; placing the mask 10 on the substrate 30, and enabling the projection of the hollow-out portion 102 on the substrate to coincide with the projection of the thin film layer pattern 20 to be formed on the substrate; forming the thin film 20a on the substrate where the mask 10 is placed, wherein the first thin film portion formed at the hollow-out portion 102 is disconnected from the second thin film portion formed on the mask body 101; and stripping off the mask 10 to form the thin film layer pattern 20. A pattern of photoresist does not need to be defined by a yellow light process of coating, exposure, development and the like of the photoresist and also does not require subsequent etching and film stripping processes, and thus, the production period is greatly shortened and meanwhile, production cost is reduced. In addition, due to no demand for the yellow light and etching processes, a probability that the thin film layer pattern 20 has defects is greatly reduced, so that product yield is effectively promoted.

For example, the thin film 20a is formed on the substrate 30 where the mask 10 is placed, by a sputtering method.

With respect to the case that deposition is carried out on the substrate 30 where the mask 10 is placed by Plasma Enhanced Chemical Vapor Deposition (PECVD) to form the thin film 20a so as to generate the problem of static electricity, the embodiment of the present disclosure can avoid the problem by adopting the sputtering method.

For example, the mask 10 is a metal mask.

The mask 10 adopting a metal material is difficult to deform, so that the thin film layer pattern 20 formed at the hollow-out portion 102 of the mask 10 can be guaranteed to be a desired pattern, and after the thin film 20a is formed, the mask 10 can be conveniently stripped off.

For example, a thickness of the metal mask 10 is between 720 μm and 880 μm.

Therefore, the thin film formed at the hollow-out portion 102 can be further guaranteed to be disconnected from the thin film formed on the mask body 101.

An embodiment of the present disclosure further provides a preparation method of a thin film transistor, including: forming a gate electrode, a gate insulating layer, a semiconductor active layer, a source electrode and a drain electrode on a base substrate, wherein at least one of the gate electrode, the semiconductor active layer, the source electrode and the drain electrode are prepared by the preparation method of the thin film layer pattern.

Namely, by using the method of forming the thin film layer pattern 20, the gate electrode can be formed, and/or the semiconductor active layer can be formed, and/or the source electrode and the drain electrode can be formed.

When the gate electrode is formed by the method of forming the thin film layer pattern 20, the thin film 20a is a conductive metal thin film, a material of the thin film 20a, for example, can be metal or metal alloy, e.g., molybdenum, molybdenum alloy and the like.

When the semiconductor active layer is formed by the method of forming the thin film layer pattern 20, the thin film 20a is a semiconductor thin film, and a material of the thin film 20a, for example, can be amorphous silicon, poly silicon, metal oxide semiconductors and the like.

When the source electrode and the drain electrode are formed by the method of forming the thin film layer pattern 20, the thin film 20a is a conductive metal thin film, and a material of the thin film 20a, for example, can be metal or metal alloy, e.g., molybdenum, molybdenum alloy, aluminium, aluminium alloy, titanium and the like.

Furthermore, in consideration of a high requirement for a migration rate of the thin film transistor at present, a material of the semiconductor active layer in the embodiment of the present disclosure, for example, is a metal oxide semiconductor or poly silicon. Namely, when the semiconductor active layer is formed, the material of the thin film 20a is the metal oxide semiconductor or the poly silicon.

Based on the above, an embodiment of the present disclosure provides a preparation method of a low temperature poly silicon thin film transistor. The method includes steps of:

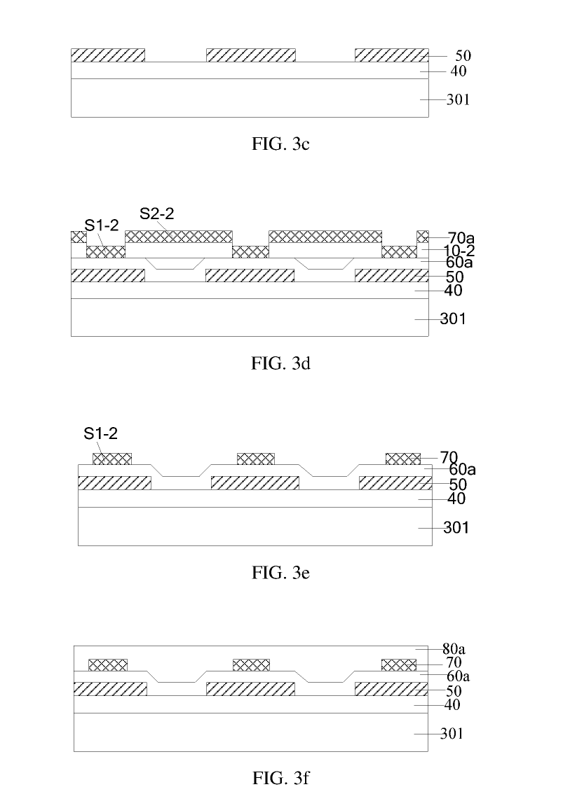

S101: as illustrated in FIG. 3a, forming a buffer layer 40 on a base substrate 301.

For example, on the pre-washed transparent base substrate 301 made of glass and the like, the buffer layer 40 is formed by a method of PECVD or sputtering and the like for stopping impurities contained in the glass from being diffused into an active layer and preventing influence on characteristics of a threshold voltage, a leakage current and the like of a thin film transistor component.

The buffer layer 40 can be a single layer of silicon oxide or silicon nitride or a lamination of the silicon oxide and the silicon nitride.

S102: as illustrated in FIG. 3a, placing a mask 10 on the substrate on which the step S101 is completed, and enabling a projection of a hollow-out portion 102-1 (not illustrated in FIG. 3a) of a mask 10-1 on the base substrate 301 to completely coincide with a projection of a semiconductor active layer to be formed on the base substrate 301.

S103: as illustrated in FIG. 3a, by adopting the sputtering method, forming an amorphous silicon thin film 50a on the substrate on which the step S102 is completed, wherein a first amorphous silicon thin film portion S1-1 formed at the hollow-out portion 102-1 is disconnected from a second amorphous silicon thin film portion S2-1 formed on the mask body 101.

S104: as illustrated in FIG. 3b, stripping off the mask 10-1 on the substrate on which the step S103 is completed, and placing the substrate subjected to stripping of the mask 10-1 in an annealing furnace to carry out dehydrogenation processing.

For example, the substrate is placed in the annealing furnace and heat preservation is carried out for a certain time so as to reduce content of hydrogen in amorphous silicon to, for example, below 2%, thereby avoiding generating the problem of hydrogen explosion when a laser annealing process is subsequently carried out.

S105: on the substrate on which the step S104 is completed, processing the amorphous silicon thin film 50a by adopting an excimer laser annealing method so as to crystallize the amorphous silicon thin film 50a to form the semiconductor active layer 50 as illustrated in FIG. 3c.

S106: as illustrated in FIG. 3d, on the substrate on which the step S105 is completed, forming a first insulating thin film 60a by adopting a PECVD method.

The first insulating thin film 60a can be a single layer of silicon oxide or silicon nitride or a lamination of the silicon oxide and the silicon nitride.

S107: as illustrated in FIG. 3d, placing a mask 10-2 on the substrate on which the step S106 is completed, and enabling a projection of a hollow-out portions 102-2 (not illustrated in FIG. 3d) of the mask 10-2 on the base substrate 301 to completely coincide with a projection of a gate electrode to be formed on the base substrate 301.

S108: as illustrated in FIG. 3d, forming a gate metal thin film 70a on the substrate on which the step S107 is completed by adopting the sputtering method, wherein a first gate metal thin film portion S1-2 formed at the hollow-out portion 102-2 is disconnected from a second gate metal thin film portion S2-2 formed on the mask body 101.

A material of the gate metal thin film 70a can be a metal or metal alloy conductive material, e.g., molybdenum, molybdenum alloy and the like.

S109: as illustrated in FIG. 3e, stripping off the mask 10-2 on the substrate on which the step S108 is completed, and reserving the first gate metal thin film portion S1-2 on the substrate so as to form the gate electrode 70.

S110: as illustrated in FIG. 3f, forming a second insulating thin film 80a on the substrate on which the step S109 is completed by adopting a PECVD method.

The second insulating thin film 80a can be a single layer of silicon oxide or silicon nitride or a lamination of the silicon oxide and the silicon nitride.

S111: as illustrated in FIG. 3g, on the substrate on which the step S110 is completed, forming a first via hole 801 for connecting a source electrode with the semiconductor active layer 50 and a second via hole 802 for connecting a drain electrode with the semiconductor active layer 50 by a patterning process, enabling the first insulating thin film 60a to form a gate insulating layer 60, and enabling the second insulating thin film 80a to form an interlayer insulating layer 80.

S112: as illustrated in FIG. 3h, on the substrate on which the step S111 is completed, placing a mask 10-3, enabling a projection of a hollow-out portion 102-3 (not illustrated in FIG. 3h) of the mask 10-3 on the base substrate 301 to completely coincide with projections of the source electrode and the drain electrode, which are to be formed, on the base substrate 301.

S113: as illustrated in FIG. 3h, on the substrate on which the step S112 is completed, forming a source and drain metal thin film 90a by adopting the sputtering method, wherein a first source and drain metal thin film portion S1-3 formed at the hollow-out portion 102-3 is disconnected from a second source and drain metal thin film portion S2-3 formed on the mask body 101.

A material of the source and drain metal thin film 90a can be a metal or metal alloy conductive material, e.g., molybdenum, molybdenum alloy, aluminium, aluminium alloy, titanium and the like.

S114: as illustrated in FIG. 3i, on the substrate on which the step S113 is completed, stripping off the mask 10-3, and reserving the first source and drain metal thin film portion S1-3 on the substrate so as to form a source electrode 901 and a drain electrode 902.

By using the steps S101 to S114, the low temperature poly silicon thin film transistor can be prepared.

An embodiment of the present disclosure provides a preparation method of an array substrate, including: forming a thin film transistor and a pixel electrode electrically connected with a drain electrode 902 of the thin film transistor on a base substrate 301, wherein the thin film transistor includes a gate electrode 70, a gate insulating layer 60, a semiconductor active layer 50, a source electrode 901 and the drain electrode 902; and at least one of the gate electrode 70, the semiconductor active layer 50, the source electrode 901, the drain electrode 902 and the pixel electrode are prepared by the method of preparing thin film layer pattern 20 as mentioned above.

Namely, by the method of forming the thin film layer pattern 20, the gate electrode 70 can be formed, and/or the semiconductor active layer 50 can be formed, and/or the source electrode 901 and the drain electrode 902 can be formed, and/or the pixel electrode can be formed.

When the pixel electrode is formed by the method of forming the thin film layer pattern 20, the thin film 20a is a transparent conductive thin film, and a material of the thin film 20a is, for example, Indium Tin Oxide (ITO), Indium Tin Zinc (IZO) and the like.

An embodiment of the present disclosure provides a preparation method of an array substrate for use in a display apparatus. Based on the steps S101 to S114, the method further includes:

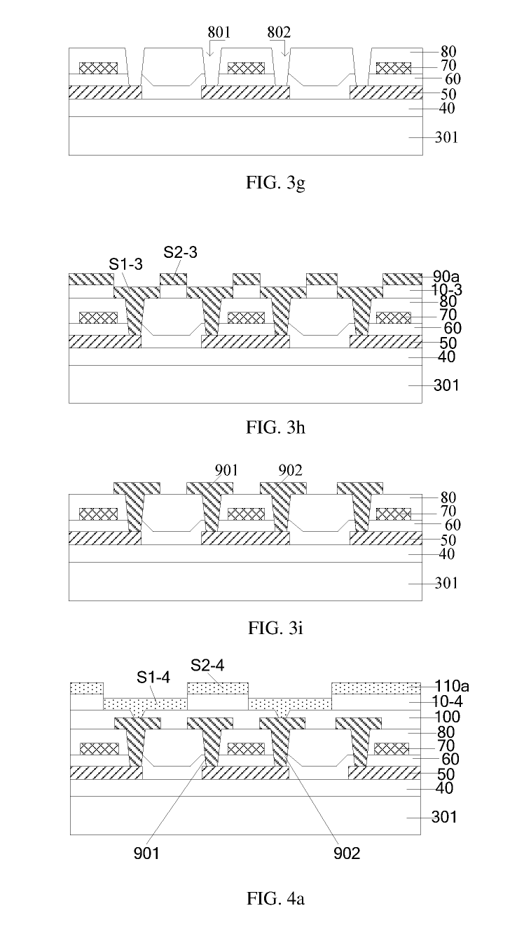

S115: as illustrated in FIG. 4a, on the substrate on which the step S114 is completed, forming a protection layer 100 including a third via hole for exposing the drain electrode 902.

S116: as illustrated in FIG. 4a, on the substrate on which the step S115 is completed, placing a mask 10-4, and enabling a projection of a hollow-out portion 102-4 (not illustrated in FIG. 4a) of the mask 10-4 on the base substrate 301 to completely coincide with a projection of the pixel electrode to be formed on the base substrate 301.

S117: as illustrated in FIG. 4a, on the substrate on which the step S116 is completed, forming a pixel transparent conductive thin film 110a by adopting the sputtering method, wherein a first pixel transparent conductive thin film portion S1-4 formed at the hollow-out portion 102-4 is disconnected from a second pixel transparent conductive thin film portion S2-4 formed on the mask body 101.

S118: as illustrated in FIG. 4b, on the substrate on which the step S116 is completed, stripping off the mask 10-4, and reserving the first pixel transparent conductive thin film portion S1-4 on the substrate so as to form a pixel electrode 110.

On such basis, the method further includes: forming a plurality of signal lines on the base substrate 301, wherein the at least one signal line is prepared by the method of preparing the thin film layer pattern 20. The signal lines include gate lines, data lines and the like. Certainly, for an array substrate in a liquid crystal display apparatus, the signal lines further include common electrode lines, and for an array substrate of an organic electroluminescence diode display apparatus, the signal lines further include power lines.

In order to simplify processes, the gate lines can be formed by using the same mask 10-2 with the gate electrode 70, i.e., the projection of the hollow-out portion 102-2 of the mask 10-2 on the base substrate 301 can completely coincide with projections of the gate lines to be formed and the gate electrode 70 on the base substrate 301.

Similarly, in order to simplify processes, the data lines can be formed by using the same mask 10-3 with the source electrode 901 and the drain electrode 902, i.e., the projection of the hollow-out portion 102-3 of the mask 10-3 on the base substrate 301 can completely coincide with projections of the data lines to be formed, the source electrode 901 and the drain electrode 902 on the base substrate 301.

An embodiment of the present disclosure further provides a preparation method of another array substrate, including: forming a thin film transistor, a pixel electrode electrically connected with a drain electrode 902 of the thin film transistor, and a common electrode on a base substrate 301, wherein the thin film transistor includes a gate electrode 70, a gate insulating layer 60, a semiconductor active layer 50, a source electrode 901 and the drain electrode 902; and at least one of the gate electrode 70, the semiconductor active layer 50, the source electrode 901, the drain electrode 902, the pixel electrode 110 and the common electrode are prepared by the method of preparing thin film layer pattern 20.

Namely, by the method of forming the thin film layer pattern 20, the gate electrode 70 can be formed, and/or the semiconductor active layer 50 can be formed, and/or the source electrode 901 and the drain electrode 902 can be formed, and/or the pixel electrode 110 can be formed, and/or the common electrode can be formed.

When the common electrode is formed by the method of forming the thin film layer pattern 20, the thin film 20a is a transparent conductive thin film, and a material of the thin film 20a, for example, is ITO, IZO and the like.

An embodiment of the present disclosure provides a preparation method of an array substrate for use in a display apparatus. Based on the steps S101 to S118, the method further includes:

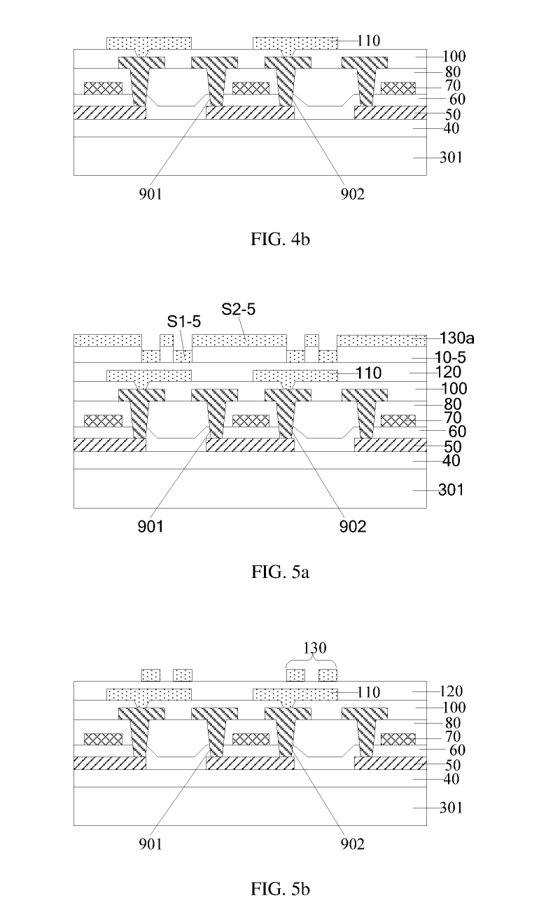

S119: as illustrated in FIG. 5a, forming a passivation layer 120 on the substrate on which the step S118 is completed.

S120: as illustrated in FIG. 5a, on the substrate on which the step S119 is completed, placing a mask 10-5, and enabling a projection of a hollow-out portion 102-5 (not illustrated in FIG. 5a) of the mask 10-5 on the base substrate 301 to completely coincide with a projection of the common electrode to be formed on the base substrate 301.

S121: as illustrated in FIG. 5a, on the substrate on which the step S120 is completed, forming a common transparent conductive thin film 130a by adopting a sputtering method, wherein a first common transparent conductive thin film portion S1-5 formed at the hollow-out portion 102-5 is disconnected from a second common transparent conductive thin film portion S2-5 formed on the mask body 101.

S122: as illustrated in FIG. 5b, stripping off the mask 10-5 on the substrate on which the step S121 is completed, and reserving the first common transparent conductive thin film portion S1-5 on the substrate so as to form the common electrode 130.

On such basis, the method further includes: forming a plurality of signal lines on the base substrate 301, wherein the at least one signal line is prepared by the method of preparing the thin film layer pattern 20. The signal lines include gate lines, data lines, common electrode lines and the like. Certainly, in order to simply processes, the gate lines and the common electrode lines can be formed by using the same mask 10-2 with the gate electrode 70, i.e., the projection of the hollow-out portion 102-2 of the mask 10-2 on the base substrate 301 can completely coincide with projections of the gate lines, the common electrode lines and the gate electrode 70, which are to be formed, on the base substrate 301.

Similarly, in order to simplify processes, the data lines can be formed by using the same mask 10-3 with the source electrode 901 and the drain electrode 902, i.e., the projection of the hollow-out portion 102-3 of the mask 10 on the base substrate can completely coincide with projections of the data lines, the source electrode 901 and the drain electrode 902 to be formed on the base substrate 301.

An embodiment of the present disclosure further provides a preparation method of yet another array substrate, including: forming a thin film transistor and an electrode layer electrically connected with a drain electrode 902 of the thin film transistor on a base substrate 301, wherein the thin film transistor includes a gate electrode 70, a gate insulating layer 60, a semiconductor active layer 50, a source electrode 901 and the drain electrode 902; and at least one of the gate electrode 70, the semiconductor active layer 50, the source electrode 901, the drain electrode 902 and the electrode layer electrically connected with the drain electrode 902 are prepared by the method of preparing thin film layer pattern 20.

For example, the electrode layer is an anode layer or a cathode layer of a light-emitting diode.

Namely, by the method of preparing the thin film layer pattern 20, the gate electrode 70 can be formed, and/or the semiconductor active layer 50 can be formed, and/or the source electrode 901 and the drain electrode 902 can be formed, and/or the electrode layer electrically connected with the drain electrode 902 can be formed.

When the electrode layer electrically connected with the drain electrode 902 is formed by the method of preparing the thin film layer pattern 20, the thin film 20a is a transparent or nontransparent conductive thin film, which is, for example, determined according to the case whether the electrode layer electrically connected with the drain electrode 902 needs light transmission and is not repeated herein.

On such basis, the method further includes: forming a plurality of signal lines on the base substrate 301, wherein the at least one signal line is prepared by the method of preparing the thin film layer pattern 20. The signal lines include gate lines, data lines, power lines and the like.

Certainly, in order to simplify processes, the gate lines and the power lines can be formed by using the same mask 10-2 with the gate electrode 70, i.e., the projection of the hollow-out portion 102-2 of the mask 10-2 on the base substrate 301 can completely coincide with projections of the gate lines and the gate electrode 70 to be formed on the base substrate 301.

Similarly, in order to simplify processes, the data lines can be formed by using the same mask 10-3 with the source electrode 901 and the drain electrode 902, i.e., the projection of the hollow-out portion 102-3 of the mask 10-3 on the base substrate 301 can completely coincide with projections of the data lines, the source electrode 901 and the drain electrode 902 to be formed on the base substrate 301.

Although the embodiment of the disclosure has been described above in great detail with general descriptions and specific embodiments, on the basis of the embodiment of the disclosure, various changes and improvements may be made, which is apparent to those skilled in the art. Therefore, all such changes and improvements without departing from the spirit of the disclosure are within the scope of the claims of the disclosure.

The present application claims priority of the Chinese Patent Application No. 201510108889.X filed on Mar. 12, 2015, the disclosure of which are incorporated herein by its reference in its entirety as part of the present application.

1. A preparation method of a thin film layer pattern, comprising:
providing a mask, the mask including a mask body and a hollow-out portion arranged on the mask body;
placing the mask on a substrate, and enabling a projection of the hollow-out portion on the substrate to coincide with a projection of the thin film layer pattern to be formed on the substrate;
forming a thin film on the substrate where the mask is placed, wherein a first portion of the thin film formed at the hollow-out portion is disconnected from a second portion of the thin film formed on the mask body; and
stripping off the mask and reserving the first portion of the thin film on the substrate so as to form the thin film layer pattern.

2. The preparation method according to claim 1, wherein the thin film is formed on the substrate provided with the mask by a sputtering method.

3. The preparation method according to claim 1, wherein the mask is a metal mask.

4. The preparation method according to claim 1, wherein a thickness of the metal mask is between 720 μm and 880 μm.

5. The preparation method according to claim 1, wherein the thin film is an amorphous silicon thin film, and the method further comprises: after stripping off the mask, carrying out an annealing processing on the first portion of the thin film reserved on the substrate so as to crystallize the first portion of the thin film.

6. A preparation method of a thin film transistor, comprising: forming a gate electrode, a gate insulating layer, a semiconductor active layer, a source electrode and a drain electrode on a substrate,
wherein at least one of the gate electrode, the semiconductor active layer, the source electrode and the drain electrode are prepared by the method according to claim 1.

7. The preparation method according to claim 6, wherein a material of the semiconductor active layer includes a metal oxide semiconductor or poly silicon.

8. A preparation method of an array substrate, comprising: forming a thin film transistor and a pixel electrode electrically connected with a drain electrode of the thin film transistor on a substrate, the thin film transistor including a gate electrode, a gate insulating layer, a semiconductor active layer, a source electrode and the drain electrode;
wherein, at least one of the gate electrode, the semiconductor active layer, the source electrode, the drain electrode and the pixel electrode are prepared by the method according to claim 1.

9. The preparation method according to claim 8, further comprising: forming a plurality of signal lines on the substrate, wherein the at least one signal line is prepared by:
providing a mask, the mask including a mask body and a hollow-out portion arranged on the mask body;
placing the mask on a substrate, and enabling a projection of the hollow-out portion on the substrate to coincide with a projection of the at least one signal line to be formed on the substrate;
forming a thin film on the substrate where the mask is placed, wherein a first portion of the thin film formed at the hollow-out portion is disconnected from a second portion of the thin film formed on the mask body; and
stripping off the mask and reserving the first portion of the thin film on the substrate so as to form the at least one signal line.

10. A preparation method of an array substrate, comprising: forming a thin film transistor, a pixel electrode electrically connected with a drain electrode of the thin film transistor, and a common electrode on a substrate; the thin film transistor including a gate electrode, a gate insulating layer, a semiconductor active layer, a source electrode and the drain electrode;
wherein, at least one of the gate electrode, the semiconductor active layer, the source electrode, the drain electrode, the pixel electrode and the common electrode are prepared by the method according to claim 1.

11. The preparation method according to claim 10, further comprising: forming a plurality of signal lines on the substrate, wherein the at least one signal line is prepared by:
providing a mask, the mask including a mask body and a hollow-out portion arranged on the mask body;
placing the mask on a substrate and enabling a projection of the hollow-out portion on the substrate to coincide with a projection of the at least one signal line to be formed on the substrate;
forming a thin film on the substrate where the mask is placed, wherein a first portion of the thin film formed at the hollow-out portion is disconnected from a second portion of the thin film formed on the mask body; and
stripping off the mask and reserving the first portion of the thin film on the substrate so as to form the at least one signal line.

12. A preparation method of an array substrate, comprising: forming a thin film transistor and an electrode layer electrically connected with a drain electrode of the thin film transistor on a substrate; the thin film transistor including a gate electrode, a gate insulating layer, a semiconductor active layer, a source electrode and the drain electrode;
wherein, at least one of the gate electrode, the semiconductor active layer, the source electrode, the drain electrode and the electrode layer electrically connected with the drain electrode are prepared by the method according to claim 1.

13. The preparation method according to claim 12, further comprising: forming a plurality of signal lines on the substrate, wherein the at least one signal line is prepared by:
providing a mask, the mask including a mask body and a hollow-out portion arranged on the mask body;
placing the mask on a substrate, and enabling a projection of the hollow-out portion on the substrate to coincide with a projection of the at least one signal line to be formed on the substrate;
forming a thin film on the substrate where the mask is placed, wherein a first portion of the thin film formed at the hollow-out portion is disconnected from a second portion of the thin film formed on the mask body; and
stripping off the mask and reserving the first portion of the thin film on the substrate so as to form the at least one signal line.

14. The preparation method according to claim 12, wherein the electrode layer is an anode or a cathode of a light-emitting diode.

15. The preparation method according to claim 6, wherein the mask is a metal mask.

16. The preparation method according to claim 6, wherein a thickness of the metal mask is between 720 μm and 880 μm.

17. The preparation method according to claim 8, wherein the mask is a metal mask.

18. The preparation method according to claim 8, wherein a thickness of the metal mask is between 720 μm and 880 μm.

19. The preparation method according to claim 10, wherein the mask is a metal mask.

20. The preparation method according to claim 10, wherein a thickness of the metal mask is between 720 μm and 880 μm.
